(19) United States
(12) Patent Application Publication
(10) Pub. No.: US 2023/0143328 A1
(43) Pub. Date: May 11, 2023

(54) ARRAY SUBSTRATE AND MANUFACTURING METHOD THEREOF

(71) Applicant: SHENZHEN CHINA STAR OPTOELECTRONICS SEMICONDUCTOR DISPLAY TECHNOLOGY CO., LTD., Shenzhen (CN)

(72) Inventors: Xuedong Mei, Shenzhen (CN); Bangyin Peng, Shenzhen (CN); Iigon Kim, Shenzhen (CN)

(73) Assignee: SHENZHEN CHINA STAR OPTOELECTRONICS SEMICONDUCTOR DISPLAY TECHNOLOGY CO., LTD., Shenzhen (CN)

(21) Appl. No.: 16/963,203

(22) PCT Filed: Jun. 3, 2020
(86) PCT No.: PCT/CN2020/094146

§ 371 Date: Jul. 17, 2020

(30) Foreign Application Priority Data
May 14, 2020 (CN) 202010407841.X

(51) Int. Cl. H01L 27/12

(52) U.S. Cl. CPC H01L 27/124; H01L 27/1262; H01L 27/1218

(57) ABSTRACT

An array substrate and a manufacturing method thereof are provided. In the array substrate, pixel electrodes are disposed on an interlayer dielectric layer, a horizontal distance from first data lines electrically connected to the pixel electrodes to the pixel electrodes is a first horizontal distance, a horizontal distance from second data lines insulated from the pixel electrodes to the pixel electrodes is a second horizontal distance, and the first horizontal distance is greater than the second horizontal distance.

### FIELD OF INVENTION

The present disclosure relates to the field of display technologies, and more particularly, to an array substrate and a manufacturing method thereof.

### BACKGROUND OF INVENTION

Since array substrates of current 8K (having resolution of 7680*4320) liquid crystal displays have small pixel sizes and large circuit densities, a coupling capacitance between data signal lines and pixel electrodes makes the liquid crystal displays have a significant vertical crosstalk phenomenon when lit, which seriously affects image quality of the 8K liquid crystal displays.

Current means to solve the vertical crosstalk are such as increasing storage capacitances and reducing drive voltages, but the above means will reduce transmittances of 8K products.

Technical problem: an embodiment of the present disclosure provides an array substrate and a manufacturing method thereof to solve the technical problem that current display panels sacrifice product transmittances to solve the vertical crosstalk.

### SUMMARY OF INVENTION

An embodiment of the present disclosure provides an array substrate, which comprises:

a device substrate;

a source and drain metal layer disposed on the device substrate and comprising a plurality of data lines arranged on the device substrate at intervals;

an interlayer dielectric layer covering the data lines; and

a plurality of pixel electrodes disposed on the interlayer dielectric layer, wherein orthographic projections of the pixel electrodes on a plane where the device substrate is located and orthographic projections of the data lines on the plane where the device substrate is located are disposed alternatingly;

wherein the data lines comprise first data lines and second data lines, a horizontal distance from the first data lines electrically connected to the pixel electrodes to the pixel electrodes is a first horizontal distance x1, a horizontal distance from the second data lines insulated from the pixel electrodes to the pixel electrodes is a second horizontal distance x2, and the first horizontal distance x1 is greater than the second horizontal distance x2; and

a signal polarity received by the first data lines is opposite to a signal polarity received by the second data lines.

In the array substrate of the embodiment of the present disclosure, the first data lines have a first width d1, and the second data lines have a second width d2; and

the first horizontal distance x1=D+Δx1, the second horizontal distance x2=D−Δx2, D is a positive number, 0<Δx1<d1/2, 0<Δx2<d2/2, and Δx1=Δx2.

The first width d1 is equal to the second width d2.

In the array substrate of the embodiment of the present disclosure, the source and drain metal layer comprises a source electrode and a drain electrode, one of the source electrode or the drain electrode is electrically connected to the data lines, and the other one of the source electrode or the drain electrode is electrically connected to the pixel electrodes.

In the array substrate of the embodiment of the present disclosure, the device substrate comprises a substrate, an active layer, a first insulating layer, a gate electrode metal layer, and a second insulating layer disposed in sequence.

An embodiment of the present disclosure further provides an array substrate which comprises:

a device substrate;

a source and drain metal layer disposed on the device substrate and comprising a plurality of data lines arranged on the device substrate at intervals;

an interlayer dielectric layer covering the data lines; and

a plurality of pixel electrodes disposed on the interlayer dielectric layer, wherein orthographic projections of the pixel electrodes on a plane where the device substrate is located and orthographic projections of the data lines on the plane where the device substrate is located are disposed alternatingly;

wherein the data lines comprise first data lines and second data lines, a horizontal distance from the first data lines electrically connected to the pixel electrodes to the pixel electrodes is a first horizontal distance x1, a horizontal distance from the second data lines insulated from the pixel electrodes to the pixel electrodes is a second horizontal distance x2, and the first horizontal distance x1 is greater than the second horizontal distance x2.

In the array substrate of the embodiment of the present disclosure, a signal polarity received by the first data lines is opposite to a signal polarity received by the second data lines.

In the array substrate of the embodiment of the present disclosure, the first data lines have a first width d1, and the second data lines have a second width d2; and

the first horizontal distance x1=D+A x1, the second horizontal distance x2=D−Δx2, D is a positive number, 0<Δx1<d1/2, 0<Δx2<d2/2, and Δx1=Δx2.

In the array substrate of the embodiment of the present disclosure, the first width d1 is equal to the second width d2.

In the array substrate of the embodiment of the present disclosure, the source and drain metal layer comprises a source electrode and a drain electrode, one of the source electrode or the drain electrode is electrically connected to the data lines, and the other one of the source electrode or the drain electrode is electrically connected to the pixel electrodes.

In the array substrate of the embodiment of the present disclosure, the device substrate comprises a substrate, an active layer, a first insulating layer, a gate electrode metal layer, and a second insulating layer disposed in sequence.

The present disclosure further relates to a manufacturing method of an array substrate, which comprises following steps:

forming a device substrate;

forming a source and drain metal layer on the device substrate, wherein the source and drain metal layer comprises a plurality of data lines arranged on the device substrate at intervals, and the data lines comprise first data lines and second data lines;

forming an interlayer dielectric layer on the source and drain metal layer; and

forming a plurality of pixel electrodes on the interlayer dielectric layer according to a first horizontal distance x1 and a second horizontal distance x2, wherein a horizontal distance from the first data lines electrically connected to the pixel electrodes to the pixel electrodes is a first horizontal distance x1, a horizontal distance from the second data lines insulated from the pixel electrodes to the pixel electrodes is a second horizontal distance x2, and the first horizontal distance x1 is greater than the second horizontal distance x2.

The manufacturing method of the array substrate provided by the embodiment of the present disclosure, further comprises:

obtaining the first horizontal distance x1 and the second horizontal distance x2, wherein the step comprises:

using a simulation software to simulate an array substrate model, wherein the array substrate model comprises first virtual data lines corresponding to the first data lines, second virtual data lines corresponding to the second data lines, and virtual pixel electrodes corresponding to the pixel electrodes, a first virtual distance is defined between the first virtual data lines and the virtual pixel electrodes, and a second virtual distance is defined between the second virtual data lines and the virtual pixel electrodes;

obtaining a first virtual coupling capacitance and a second virtual coupling capacitance according to the first virtual distance and the second virtual distance, the first virtual coupling capacitance is a coupling capacitance defined between the first virtual data lines and the virtual pixel electrodes, and the second virtual coupling capacitance is a coupling capacitance defined between the second virtual data lines and the virtual pixel electrodes;

if the first virtual coupling capacitance being not equal to the second virtual coupling capacitance, translating the first virtual data lines and the second virtual data lines to adjust the first virtual distance and the second virtual distance; and

if the first virtual coupling capacitance being equal to the second virtual coupling capacitance, obtaining the first virtual distance and the second virtual distance, and having the first virtual distance of present be the first horizontal distance x1 and the second virtual distance of present be the second horizontal distance x2.

In the manufacturing method of the array substrate provided by the embodiment of the present disclosure, the first virtual data lines have a first virtual width, and the second virtual data lines have a second virtual width;

the step of if the first virtual coupling capacitance being not equal to the second virtual coupling capacitance, translating the first virtual data lines and the second virtual data lines to adjust the first virtual distance and the second virtual distance, comprises:

if the first virtual coupling capacitance being greater than the second virtual coupling capacitance, increasing the first virtual distance and reducing the second virtual distance while maintaining a sum of the first virtual width and the second virtual width unchanged, wherein an increased amount Δx1 of the first virtual distance is equal to a reduced amount Δx2 of the second virtual distance.

In the manufacturing method of the array substrate provided by the embodiment of the present disclosure, a signal polarity received by the first data lines is opposite to a signal polarity received by the second data lines.

Beneficial effect: through defining the first horizontal distance x1 greater than the second horizontal distance x2 in an unit, the array substrate and the manufacturing method thereof of the present disclosure make a coupling capacitance between the first data lines and the pixel electrodes equal to a coupling capacitance between the second data lines and the pixel electrodes, thereby reducing a probability of vertical crosstalk. Further, when signal polarities received respectively by the first data lines and the second data lines are opposite, a coupling effect on a same pixel electrode by the two will be counteracted, thereby solving the vertical crosstalk problem.

### DESCRIPTION OF DRAWINGS

The accompanying figures to be used in the description of embodiments of the present disclosure will be described in brief to more clearly illustrate the technical solutions of the embodiments or the prior art. The accompanying figures described below are only part of the embodiments of the present disclosure, from which those skilled in the art can derive further figures without making any inventive efforts.

FIG. 1 is a schematic cross-sectional structural diagram of an array substrate according to an embodiment of the present disclosure.

FIG. 2 is a schematic structural top view of an array substrate according to an embodiment of the present disclosure.

FIG. 3 is a schematic structural diagram of a unit of an array substrate according to an embodiment of the present disclosure.

FIG. 4 is a flowchart of a manufacturing method of an array substrate according to an embodiment of the present disclosure.

### DETAILED DESCRIPTION OF PREFERRED EMBODIMENTS

The technical solutions in the embodiments of the present disclosure will be clearly and completely described below with reference to the drawings in the embodiments of the present disclosure. Obviously, the described embodiments are only a part of the embodiments of the present disclosure, but not all the embodiments. Based on the embodiments in the present disclosure, all other embodiments obtained by those skilled in the art without creative efforts are within the scope of the present disclosure.

In the description of the present disclosure, it should be understood that terms such as “center”, “longitudinal”, “lateral”, “length”, “width”, “thickness”, “upper”, “lower”, “front”, “rear”, “left”, “right”, “vertical”, “horizontal”, “top”, “bottom”, “inside”, “outside”, “clockwise”, “counter-clockwise”, as well as derivative thereof should be construed to refer to the orientation as described or as shown in the drawings under discussion. These relative terms are for convenience of description, do not require that the present disclosure be constructed or operated in a particular orientation, and shall not be construed as causing limitations to the present disclosure. In addition, terms such as “first” and “second” are used herein for purposes of description and are not intended to indicate or imply relative importance or implicitly indicating the number of technical features indicated. Thus, features limited by “first” and “second” are intended to indicate or imply including one or more than one these features. In the description of the present disclosure, “a plurality of” relates to two or more than two, unless otherwise specified.

In the description of the present disclosure, it should be noted that unless there are express rules and limitations, the terms such as “mount,” “connect,” and “bond” should be comprehended in broad sense. For example, it can mean a permanent connection, a detachable connection, or an integrated connection; it can mean a mechanical connection, an electrical connection, or can communicate with each other; it can mean a direct connection, an indirect connection by an intermediary, or an inner communication or an inter-reaction between two elements. A person skilled in the art should understand the specific meanings in the present disclosure according to specific situations.

In the description of the present disclosure, unless specified or limited otherwise, it should be noted that, a structure in which a first feature is “on” or “beneath” a second feature may include an embodiment in which the first feature directly contacts the second feature and may also include an embodiment in which an additional feature is formed between the first feature and the second feature so that the first feature does not directly contact the second feature. Furthermore, a first feature “on,” “above,” or “on top of” a second feature may include an embodiment in which the first feature is right “on,” “above,” or “on top of” the second feature and may also include an embodiment in which the first feature is not right “on,” “above,” or “on top of” the second feature, or just means that the first feature has a sea level elevation greater than the sea level elevation of the second feature. While first feature “beneath,” “below,” or “on bottom of” a second feature may include an embodiment in which the first feature is right “beneath,” “below,” or “on bottom of” the second feature and may also include an embodiment in which the first feature is not right “beneath,” “below,” or “on bottom of” the second feature, or just means that the first feature has a sea level elevation less than the sea level elevation of the second feature.

The following description provides many different embodiments or examples for implementing different structures of the present disclosure. In order to simplify the present disclosure, the components and settings of a specific example are described below. Of course, they are merely examples and are not intended to limit the present disclosure. In addition, the present disclosure may repeat reference numerals and/or reference letters in different examples, which are for the purpose of simplicity and clarity, and do not indicate the relationship between the various embodiments and/or arrangements discussed. In addition, the present disclosure provides examples of various specific processes and materials, but one of ordinary skill in the art will recognize the use of other processes and/or the use of other materials.

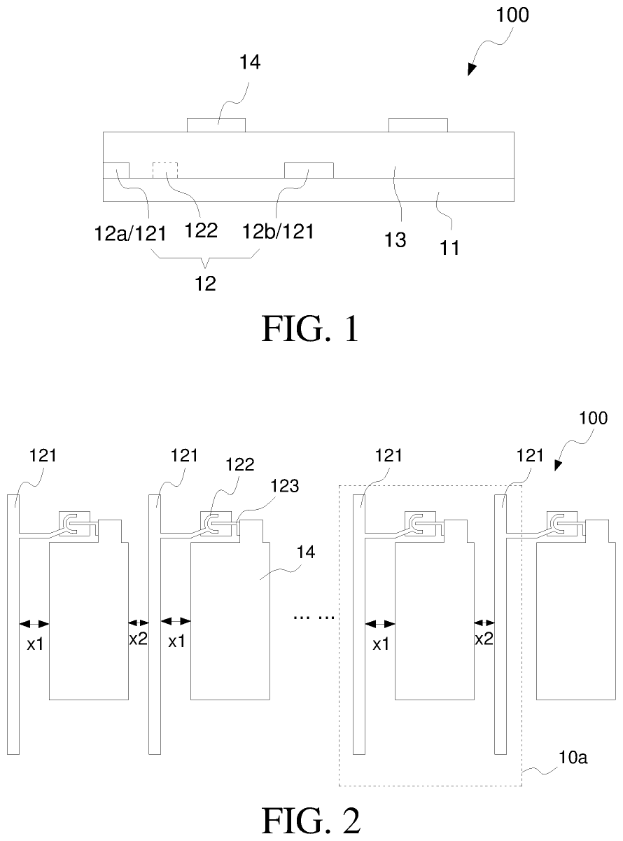

Referring to FIGS. 1 and 2, FIG. 1 is a schematic cross-sectional structural diagram of an array substrate according to an embodiment of the present disclosure, and FIG. 2 is a schematic structural top view of the array substrate according to the embodiment of the present disclosure.

The embodiment of the present disclosure provides an array substrate 100, which includes a device substrate 11, a source and drain metal layer 12, an interlayer dielectric layer 13, and a plurality of pixel electrodes 14.

The device substrate 11 comprises a substrate, an active layer, a first insulating layer, a gate electrode metal layer, and a second insulating layer disposed in sequence. In some embodiments, the device substrate 11 may be the active layer disposed on the gate electrode metal layer, that is, thin film transistors of the array substrate 100 may be a top gate type structure.

The source and drain metal layer 12 is disposed on the device substrate 11. The source and drain metal layer 12 includes a plurality of data lines 121, a source electrode 122, and a drain electrode 123. The data lines 121 are arranged on the device substrate 11 at intervals. One of the source electrode 122 or the drain electrode 123 is electrically connected to the data lines 121, and the other one of the source electrode 122 or the drain electrode 123 is electrically connected to the pixel electrodes 14. In the embodiment, the source electrode 122 is electrically connected to the data lines 121, and the drain electrode 123 is electrically connected to the pixel electrodes 14.

The interlayer dielectric layer covers the data lines 121.

The pixel electrodes 14 are disposed on the interlayer dielectric layer 13. Orthographic projections of the pixel electrodes 14 on a plane where the device substrate 11 is located and orthographic projections of the data lines 121 on the plane where the device substrate is located are disposed alternatingly.

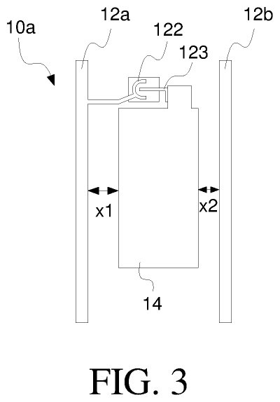

The array substrate 100 includes a plurality of units 10a. Referring to FIG. 3, one of the pixel electrodes 14 and two adjacent data lines 121 thereof constitute one of the units 10a. The data lines 121 include first data lines 12a and second data lines 12b.

In each of the units 10a, a horizontal distance from a first data line 12a which is electrically connected to a pixel electrode 14 to the pixel electrode 14 is a first horizontal distance x1, a horizontal distance from a second data line 12b which is insulated from the pixel electrode 14 to the pixel electrode 14 is a second horizontal distance x2, and the first horizontal distance x1 is greater than the second horizontal distance x2.

Through defining the first horizontal distance x1 greater than the second horizontal distance x2 in the unit 10a, the array substrate 100 of the present disclosure makes a coupling capacitance between the first data line 12a and the pixel electrode 14 equal to a coupling capacitance between the second data line 12b and the pixel electrode 14, thereby reducing a probability of vertical crosstalk.

Specifically, in current technology, one pixel electrode and two adjacent data lines thereof are taken as an example. Since distances from the pixel electrode to the adjacent data lines thereof are equal, and in addition to a vertical segment, a data line which is electrically connected to the pixel electrode further includes a wire segment connecting the vertical segment and a source electrode, thereby making an area of the data line facing the pixel electrode being greater than an area of the other data line facing the pixel electrode. Therefore, after receiving signals, a coupling capacitance between the pixel electrode and the data line which is electrically connected to the pixel electrode will be greater than a coupling capacitance between the pixel electrode and the other data line which is insulated from the pixel electrode, thereby causing the vertical crosstalk. Meanwhile, existing solutions are to increase a storage capacitance or to reduce a drive voltage, but the above solutions sacrifice transmittances of products.

Therefore, in the array substrate 100 in the embodiment, in a situation without changing widths of the first data lines 12a and the second data lines 12b, without reducing a drive voltage received by the data lines 12, and without increasing a storage capacitance, only the first horizontal distance x1 and the second horizontal distance x2 are adjusted to reduce the probability of vertical crosstalk, that is, when the embodiment is used to compose a display panel, the solution of the embodiment can prevent the transmittance of the display panel from being sacrificed.

Further, when a signal polarity received by the first data line 12a is opposite to a signal polarity received by the second data line 12b, a coupling effect on the same pixel electrode 14 by the two will be counteracted, thereby solving the vertical crosstalk problem. For example, in the array substrate 100 of the embodiment, when the data lines 121 in odd columns receive a positive signal, the data lines 121 in even columns receive a negative signal, and vice versa.

In the array substrate 100 of the embodiment, the first data lines 12a have a first width d1, and the second data lines 12b have a second width d2.

The first horizontal distance x1=D+A x1, the second horizontal distance x2=D−Δx2, D is a positive number, 0<Δx1<d1/2, 0<Δx2<d2/2, and Δx1=Δx2.

Specifically, in the unit 10a, a determination process of the first horizontal distance x1 and the second horizontal distance x2 is: maintaining a position of the pixel electrode 14 unchanged, and adjusting the first horizontal distance x1 and the second horizontal distance x2 by translating the first data line 12a and the second data line 12b along a direction at the same time. In addition, a translational amount Δx1 of the first data line 12a is equal to a translational amount Δx2 of the second data line 12b, that is, the translational amount Δx1 of the first data line 12a is equal to an increased amount of the first horizontal distance x1 compared to an original state thereof, and the translational amount Δx2 of the second data line 12b is equal to a reduced amount of the second horizontal distance x2 compared to an original state thereof.

The embodiment uses a way to translate a same distance, which is convenient for the array substrate 100 to perform duplicated preparation of units 10a without adjusting the first horizontal distance x1 and the second horizontal distance x2 in each of the units 10a, and improves early manufacturing efficiency greatly.

In addition, the disposition of 0<Δx1<d1/2 and 0<Δx2<d2/2 prevents distances between data lines 121 and other wirings from being too close and affecting each other's layouts, thereby preventing adding difficulty to the process.

In addition, the disposition of the first width d1 being equal to the second width d2 can ensure selectable ranges of Δx1 and Δx2 are consistent, which is convenient for selecting the same translation amount and is also a basis for the units 10a to perform the duplicated preparation.

A manufacturing method of the array substrate 100 of this embodiment is a manufacturing method of an array substrate in the following embodiment. The specific manufacturing process of the array substrate 100 can be referred to the manufacturing method of the array substrate in the following embodiment, which will not be repeated here.

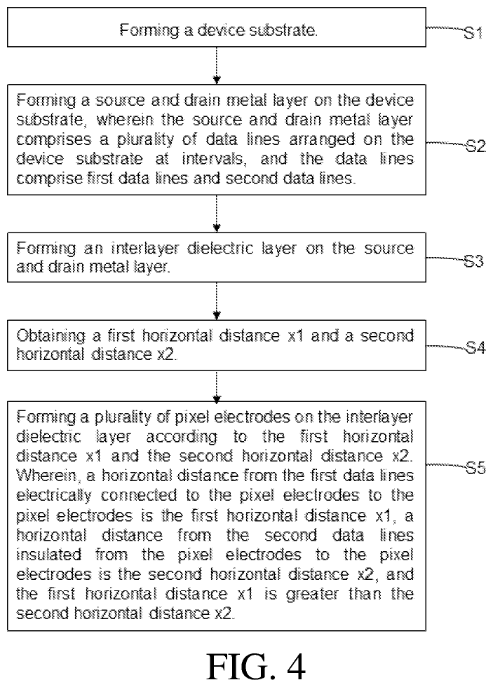

Referring to FIG. 4 and combined with FIGS. 1 and 2, the present disclosure further relates to the manufacturing method of the array substrate 100, which includes following steps.

Step S1: forming the device substrate 11.

Step S2: forming the source and drain metal layer 12 on the device substrate 11, wherein the source and drain metal layer 12 comprises the plurality of data lines 121 arranged on the device substrate at intervals, and the data lines comprise the first data lines and the second data lines.

Step S3: forming the interlayer dielectric layer 13 on the source and drain metal layer 12.

Step S4: obtaining the first horizontal distance x1 and the second horizontal distance x2.

Step S5: forming the plurality of pixel electrodes 14 on the interlayer dielectric layer according to the first horizontal distance x1 and the second horizontal distance x2. Wherein, a horizontal distance from the first data lines 12a electrically connected to the pixel electrodes 14 to the pixel electrodes 14 is the first horizontal distance x1, a horizontal distance from the second data lines 12b insulated from the pixel electrodes 14 to the pixel electrodes 14 is the second horizontal distance x2, and the first horizontal distance x1 is greater than the second horizontal distance x2.

Through defining the first horizontal distance x1 greater than the second horizontal distance x2 in units, the manufacturing method of the array substrate of the present disclosure makes a coupling capacitance between the first data lines and the pixel electrodes 14 equal to a coupling capacitance between the second data lines and the pixel electrodes 14, thereby reducing the probability of vertical crosstalk.

The following is an explanation of the manufacturing method of the array substrate in this embodiment.

Step S1: forming the device substrate 11. The device substrate 11 comprises a substrate, an active layer, a first insulating layer, a gate electrode metal layer, and a second insulating layer disposed in sequence. In some embodiments, the device substrate 11 may be the active layer disposed on the gate electrode metal layer, that is, thin film transistors of the array substrate 100 may be a top gate type structure.

Then proceed to step S2.

Step S2: forming the source and drain metal layer 12 on the device substrate 11, wherein the source and drain metal layer 12 comprises the plurality of data lines 121 arranged on the device substrate at intervals, and the data lines comprise the first data lines and the second data lines.

The first data lines 12a have a first width d1, and the second data lines 12b have a second width d2. Optionally, the first width d1 is equal to the second width d2.

In addition, the source and drain metal layer 12 further includes the source electrode 122 and the drain electrode 123. One of the source electrode 122 or the drain electrode 123 is electrically connected to the data lines 121, and the other one of the source electrode 122 or the drain electrode 123 is electrically connected to the pixel electrodes 14. In the embodiment, the source electrode 122 is electrically connected to the data lines 121, and the drain electrode 123 is electrically connected to the pixel electrodes 14.

Then proceed to step S3.

Step S3: forming the interlayer dielectric layer 13 on the source and drain metal layer 12. Then proceed to step S4.

Step S4: obtaining the first horizontal distance x1 and the second horizontal distance x2. Wherein, the first horizontal distance x1 is greater than the second horizontal distance x2. It should be noted that the step S4 only needs to be before step S5, that is, the step S4 may be before the step S1 or between the step S1 and the step S2, and so on.

Specifically, the step S4 includes following steps:

Step S41: using a simulation software to simulate an array substrate model. The array substrate model comprises first virtual data lines corresponding to the first data lines, second virtual data lines corresponding to the second data lines, and virtual pixel electrodes corresponding to the pixel electrodes, the first virtual data lines have a first virtual width, the second virtual data lines have a second virtual width, a first virtual distance is defined between the first virtual data lines and the virtual pixel electrodes, and a second virtual distance is defined between the second virtual data lines and the virtual pixel electrodes.

Step S42: obtaining a first virtual coupling capacitance and a second virtual coupling capacitance according to the first virtual distance and the second virtual distance, the first virtual coupling capacitance is a coupling capacitance defined between the first virtual data lines and the virtual pixel electrodes, and the second virtual coupling capacitance is a coupling capacitance defined between the second virtual data lines and the virtual pixel electrodes.

Step S43: if the first virtual coupling capacitance being not equal to the second virtual coupling capacitance, translating the first virtual data lines and the second virtual data lines to adjust the first virtual distance and the second virtual distance.

Step S44: if the first virtual coupling capacitance being equal to the second virtual coupling capacitance, obtaining the first virtual distance and the second virtual distance, and having the first virtual distance of present be the first horizontal distance x1 and the second virtual distance of present be the second horizontal distance x2.

Wherein, in the step S41, a framework of the array substrate model coincides with a framework of the array substrate, which means except variable factors of the array substrate model that may be different from the array substrate, relative positions of other structures and devices are all the same. In the manufacturing method of the array substrate of this embodiment, the variable factors of the array substrate model are the first virtual distance and the second virtual distance.

In the step S42, the first virtual distance and the second virtual distance are assumed to be equal, and the first virtual coupling capacitance and the second virtual coupling capacitance of present are obtained according to the above condition.

In the step S43, magnitudes of the first virtual coupling capacitance and the second virtual coupling capacitance of present are determined, if the first virtual coupling capacitance is greater than the second virtual coupling capacitance, the first virtual distance is increased and the second virtual distance is reduced while a sum of the first virtual width and the second virtual width remains unchanged, and an increased amount Δx1 of the first virtual distance is equal to a reduced amount Δx2 of the second virtual distance.

In addition, the disposition of 0<Δx1<d1/2 and 0<Δx2<d2/2 prevents distances between the data lines 121 manufactured in a subsequent process and other wirings from being too close to affect each other's layouts, thereby preventing adding difficulty to the process.

In the step S44, the first virtual distance and the second virtual distance are adjusted to make the first virtual coupling capacitance being equal to the second virtual coupling capacitance. When the first virtual coupling capacitance is equal to the second virtual coupling capacitance, the first virtual distance and the second virtual distance of present are obtained, and correspondingly having the first virtual distance of present be the first horizontal distance x1 and the second virtual distance of present be the second horizontal distance x2.

Then proceed to step S5.

Step S5: forming the plurality of pixel electrodes 14 on the interlayer dielectric layer 13 according to the first horizontal distance x1 and the second horizontal distance x2.

Wherein, taking one of the pixel electrodes 14 and two adjacent data lines 121 as one of the units 10a, in each of the units 10a, a horizontal distance from a first data line 12a electrically connected to a pixel electrode 14 to the pixel electrode 14 is the first horizontal distance x1, and a horizontal distance from a second data line 12b insulated from the pixel electrode 14 to the pixel electrodes 14 is the second horizontal distance x2. The first horizontal distance x1 is greater than the second horizontal distance x2.

In the manufacturing method of the array substrate 100 in the embodiment, in a situation of without changing widths of the first data lines 12a and the second data lines 12b, without reducing a drive voltage received by the data lines 12, and without increasing a storage capacitance, only the first horizontal distance x1 and the second horizontal distance x2 are adjusted to reduce the probability of vertical crosstalk, that is, when the embodiment is used to compose a display panel, the solution of the embodiment can prevent the transmittance of the display panel from being sacrificed.

Further, when a signal polarity received by the first data line 12a is opposite to a signal polarity received by the second data line 12b, a coupling effect on the same pixel electrode 14 by the two will be counteracted, thereby solving the vertical crosstalk problem. For example, in the array substrate 100 of the embodiment, when the data lines 121 in odd columns receive a positive signal, the data lines 121 in even columns receive a negative signal, and vice versa.

In this way, the manufacturing method of the array substrate in the embodiment is completed. Wherein, a structure of the array substrate coincides with a structure of the array substrate 100 in the above embodiment. For details, please refer to the description of the array substrate 100 in the above embodiment.

Through defining the first horizontal distance x1 greater than the second horizontal distance x2 in an unit, the array substrate and the manufacturing method thereof of the present disclosure make a coupling capacitance between the first data lines and the pixel electrodes equal to a coupling capacitance between the second data lines and the pixel electrodes, thereby reducing a probability of vertical crosstalk. Further, when signal polarities received respectively by the first data lines and the second data lines are opposite, a coupling effect on a same pixel electrode by the two will be counteracted, thereby solving the vertical crosstalk problem.

The array substrate and the manufacturing method thereof provided by the embodiments of the present disclosure are described in detail above. The specific examples are applied in the description to explain the principle and implementation of the disclosure. The description of the above embodiments is only for helping to understand the technical solution of the present disclosure and its core ideas, and it is understood that many changes and modifications to the described embodiment can be carried out without departing from the scope and the spirit of the disclosure that is intended to be limited only by the appended claims.

What is claimed is:

1. An array substrate, comprising:
a device substrate;
a source and drain metal layer disposed on the device substrate and comprising a plurality of data lines arranged on the device substrate at intervals;
an interlayer dielectric layer covering the data lines; and
a plurality of pixel electrodes disposed on the interlayer dielectric layer, wherein orthographic projections of the pixel electrodes on a plane where the device substrate is located and orthographic projections of the data lines on the plane where the device substrate is located are disposed alternatingly;
wherein the data lines comprise first data lines and second data lines, a horizontal distance from the first data lines electrically connected to the pixel electrodes to the pixel electrodes is a first horizontal distance x1, a horizontal distance from the second data lines insulated from the pixel electrodes to the pixel electrodes is a second horizontal distance x2, and the first horizontal distance x1 is greater than the second horizontal distance x2;
a signal polarity received by the first data lines is opposite to a signal polarity received by the second data lines;
the first data lines have a first width d1, and the second data lines have a second width d2; and
the first horizontal distance x1=D+Δx1, the second horizontal distance x2=D−Δx2, D is a positive number, 0<Δx1<d1/2, 0<Δx2<d2/2, and Δx1=Δx2.

2. The array substrate according to claim 1, wherein the first width d1 is equal to the second width d2.

3. The array substrate according to claim 1, wherein the source and drain metal layer comprises a source electrode and a drain electrode, one of the source electrode or the drain electrode is electrically connected to the data lines, and the other one of the source electrode or the drain electrode is electrically connected to the pixel electrodes.

4. The array substrate according to claim 1, wherein the device substrate comprises a substrate, an active layer, a first insulating layer, a gate electrode metal layer, and a second insulating layer disposed in sequence.

5. An array substrate, comprising:
a device substrate;
a source and drain metal layer disposed on the device substrate and comprising a plurality of data lines arranged on the device substrate at intervals;
an interlayer dielectric layer covering the data lines; and
a plurality of pixel electrodes disposed on the interlayer dielectric layer, wherein orthographic projections of the pixel electrodes on a plane where the device substrate is located and orthographic projections of the data lines on the plane where the device substrate is located are disposed alternatingly; and
wherein the data lines comprise first data lines and second data lines, a horizontal distance from the first data lines electrically connected to the pixel electrodes to the pixel electrodes is a first horizontal distance x1, a horizontal distance from the second data lines insulated from the pixel electrodes to the pixel electrodes is a second horizontal distance x2, and the first horizontal distance x1 is greater than the second horizontal distance x2.

6. The array substrate according to claim 5, wherein a signal polarity received by the first data lines is opposite to a signal polarity received by the second data lines.

7. The array substrate according to claim 5, wherein the first data lines have a first width d1, and the second data lines have a second width d2; and
the first horizontal distance x1=D+Δx1, the second horizontal distance x2=D−Δx2, D is a positive number, 0<Δx1<d1/2, 0<Δx2<d2/2, and Δx1=Δx2.

8. The array substrate according to claim 7, wherein the first width d1 is equal to the second width d2.

9. The array substrate according to claim 5, wherein the source and drain metal layer comprises a source electrode and a drain electrode, one of the source electrode or the drain electrode is electrically connected to the data lines, and the other one of the source electrode or the drain electrode is electrically connected to the pixel electrodes.

10. The array substrate according to claim 5, wherein the device substrate comprises a substrate, an active layer, a first insulating layer, a gate electrode metal layer, and a second insulating layer disposed in sequence.

11. A manufacturing method of an array substrate, comprising following steps:
forming a device substrate;
forming a source and drain metal layer on the device substrate, wherein the source and drain metal layer comprises a plurality of data lines arranged on the device substrate at intervals, and the data lines comprise first data lines and second data lines;
forming an interlayer dielectric layer on the source and drain metal layer; and
forming a plurality of pixel electrodes on the interlayer dielectric layer according to a first horizontal distance x1 and a second horizontal distance x2, wherein a horizontal distance from the first data lines electrically connected to the pixel electrodes to the pixel electrodes is a first horizontal distance x1, a horizontal distance from the second data lines insulated from the pixel electrodes to the pixel electrodes is a second horizontal distance x2, and the first horizontal distance x1 is greater than the second horizontal distance x2.

12. The manufacturing method of the array substrate according to claim 11, further comprising:
obtaining the first horizontal distance x1 and the second horizontal distance x2, wherein the step comprises:
using a simulation software to simulate an array substrate model, wherein the array substrate model comprises first virtual data lines corresponding to the first data lines, second virtual data lines corresponding to the second data lines, and virtual pixel electrodes corresponding to the pixel electrodes, a first virtual distance is defined between the first virtual data lines and the virtual pixel electrodes, and a second virtual distance is defined between the second virtual data lines and the virtual pixel electrodes;
obtaining a first virtual coupling capacitance and a second virtual coupling capacitance according to the first virtual distance and the second virtual distance, the first virtual coupling capacitance is a coupling capacitance defined between the first virtual data lines and the virtual pixel electrodes, and the second virtual coupling capacitance is a coupling capacitance defined between the second virtual data lines and the virtual pixel electrodes;
if the first virtual coupling capacitance being not equal to the second virtual coupling capacitance, translating the first virtual data lines and the second virtual data lines to adjust the first virtual distance and the second virtual distance; and
if the first virtual coupling capacitance being equal to the second virtual coupling capacitance, obtaining the first virtual distance and the second virtual distance, and having the first virtual distance of present be the first horizontal distance x1 and the second virtual distance of present be the second horizontal distance x2.

13. The manufacturing method of the array substrate according to claim 12, wherein the first virtual data lines have a first virtual width, and the second virtual data lines have a second virtual width;
the step of if the first virtual coupling capacitance being not equal to the second virtual coupling capacitance, translating the first virtual data lines and the second virtual data lines to adjust the first virtual distance and the second virtual distance, comprises:
if the first virtual coupling capacitance being greater than the second virtual coupling capacitance, increasing the first virtual distance and reducing the second virtual distance while maintaining a sum of the first virtual width and the second virtual width unchanged, wherein an increased amount Δx1 of the first virtual distance is equal to a reduced amount Δx2 of the second virtual distance.

14. The manufacturing method of the array substrate according to claim 11, wherein a signal polarity received by the first data lines is opposite to a signal polarity received by the second data lines.
